(19) United States
(12) Patent Application Publication
(10) Pub. No.: US 2008/0205159 A1
(43) Pub. Date: Aug. 28, 2008

(54) VERIFICATION PROCESS OF A FLASH MEMORY

(75) Inventor: Chun-Yu Liao, Taichung City (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: MACRONIX INTERNATIONAL CO., LTD., Hsinchu (TW)

(21) Appl. No.: 11/679,205

(22) Filed: Feb. 27, 2007

(51) Int. Cl. G11C 16/34

(52) U.S. Cl. 365/185.22

(57) ABSTRACT

A verification process is disclosed for verifying correctness of a data status of a flash memory after data of the flash memory is altered. The flash memory has a plurality of memory cells array and a volatile memory. The verification process includes reading memory-cell verification data stored in the volatile memory, wherein the memory-cell verification data is for indicating a previous verification result of each memory cell is ‘success’ or ‘failure’; and performing a verification procedure on the memory cells failed in previous verification according to the memory-cell verification data, but not on the remained memory cells successful in previous verification.

### BACKGROUND OF THE INVENTION

1. Field of the Invention

The invention relates in general to a flash memory, and more particularly to a verification process of a flash memory.

2. Description of the Related Art

Non-volatile memory stores logic data 0/1 via memory cells. Each memory cell includes a transistor having a gate, source and drain electrode. By applying a potential pulse to the gate, source and drain to change charge amount in a memory layer of the transistor, a threshold voltage of the transistor can be set. The memory layer is, for example, a polysilicon layer or non-conducting silicon nitride layer. The non-volatile memory denotes different logic data according to the amount of charges stored in the memory layer.

In order to verify whether the threshold voltage of a memory cell reaches a preset voltage, in a program flow of the non-volatile memory, a verification procedure will be provided. The verification procedure is performed after the memory is programmed. That is, after a specific amount of memory cells, such as the amount of memory cells in a page, is programmed, the verification process is performed on the memory cells. For example, in the verification process, the threshold voltages of the memory cells are read and verified if each of the threshold voltages reaches the preset voltage. If some memory cells are failed during verification process, the programming flow will be repeated for the failed memory cells or all the memory cells. However, after re-programming, the program flow will perform a verification process again on the memory cells to ensure that every memory cell has a threshold voltage up to the preset value.

In terms of a multi-level memory cell, such as a silicon-oxide-nitride-oxide-silicon (SONOS) memory, a SONOS memory cell can store 2-bits logic data (00, 01, 10, 11) and thus it takes longer time to determine what the logic data is when reading this kind of memory cell. Therefore, in the program flow, the verification process takes longer time to read out all the logic data stored in the memory cells. As a result, the program flow will become longer since it needs more time to wait for all the memory cells to be read in the verification process. For this reason, how to reduce the verification process time for programming the SONOS memory cells is indeed an issue to be solved by relevant industrials.

### SUMMARY OF THE INVENTION

The invention discloses a fast verification process to speed up the whole program process.

The invention provides a verification process for verifying correctness of a data status of a flash memory after data of the flash memory is altered. The flash memory has a plurality of memory cells array and a random access memory (RAM). The RAM is an SRAM or Registers or Latches. The verification process includes reading memory-cell verification data stored in the RAM, wherein the memory-cell verification data is for indicating a previous verification result of each memory cell that is ‘success’ or ‘failure’; and performing a verification procedure on the memory cells failed in previous verification according to the memory-cell verification data, but not on the remaining successful memory cells in previous verification.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 is a flow chart of a verification process according to a preferred embodiment of the invention.

FIG. 2 is a flow chart of a program flow.

### DETAILED DESCRIPTION OF THE INVENTION

The invention provides a verification process. In the verification process, memory-cell verification data stored in a temporary memory of a memory device is first read and a verification procedure (reading, comparing and recording a verification result) is performed on the memory cells failed in previous verification according to the memory-cell verification data to reduce time for the verification process and thus speed up the program flow. The temporary memory is a volatile memory, for example, a random access memory (RAM) or a dynamic RAM (DRAM).

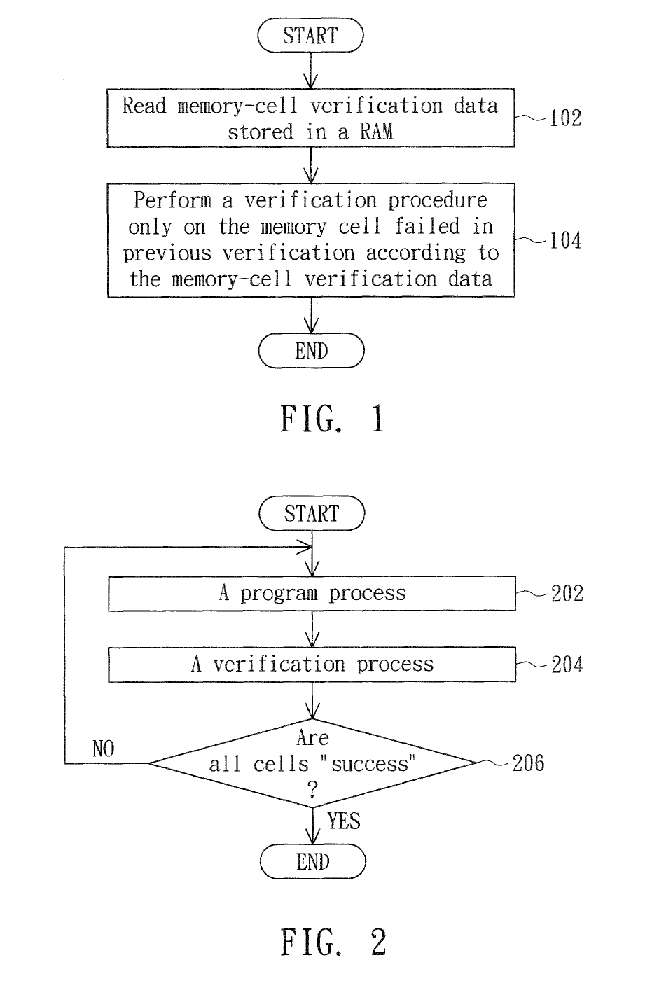

Referring to FIG. 1, a flow chart of a verification process according to a preferred embodiment of the invention is shown. The verification process is for verifying correctness of a data status of a flash memory after data stored in the flash memory is altered. The flash memory is a non-volatile memory, such as a SONOS memory. The flash memory has a number of memory cells in array and a RAM. The RAM is a SRAM or Registers or Latches. First, in step 102, read memory-cell verification data stored in the RAM. The memory-cell verification data is used for indicating a previous verification result of each memory cell is ‘success’ or ‘failure’. Following that, in step 104, perform a verification procedure only on the memory cells failed in previous verification but not the memory cells successful in verification in order to reduce time for reading data in the memory cells in the verification procedure. The step in performing a verification procedure further includes recording the address of any memory cell failed in present verification into the RAM as new memory-cell verification data.

In the following, how the invention can effectively reduce time for verification process will be illustrated in a concrete way. For example, in a program flow, the verification process is performed after programming. As shown in FIG. 2, which is a flow chart of a program flow the program flow s includes two main process. Step 202 is a programming process and step 204 is a verification process of the invention. In 202, the programming process is used to program the memory cells according to the logic data to be written into the memory cells. For example, in the program process, first program a number of memory cells corresponding to a written unit in the flash memory, all or part of the written unit may be program in the same time. In program definition, a written unit may be corresponding to a page, such as program the memory cells to be written with “0”. Afterward, when the verification process 204 is performed, read the verification status of the memory cells corresponding to the page in the RAM to determine which memory cells should be read in the memory cells corresponding to the page and verify whether a data status is correct. That is, in the verification process, the invention will not read the memory cells first, but obtain which memory cells needs to be verified in present verification process from RAM. Then, a verification procedure (including reading, comparing and recording a result of the present verification) is performed on the memory cells to be verified. In 206, if there is any memory cells to be verified, step 202 will be repeated until verification is completed. The next address need to be verified may be searched in the RAM during verification procedure (step 102 and 104 may be operated at the same time).

The speed for reading a RAM is far larger than that for reading a memory cell. For example, reading data stored in a memory cell takes 500 ns while reading a piece of verification data corresponding to an address of a memory cell in the memory-cell verification data takes only 50 ns. A programmed unit is corresponding to 512 bytes and 8 bits of data are read out or written in at a time. Under the situation that the page has only two memory cells to be verified and, for example, two memory cells failed in verification are recorded in the previous verification, the present program process is performed on the two memory cells only. In a conventional verification process, the verification procedure is performed on all the memory cells corresponding to the page after programming, and thus it takes 512*500 ns=256 us, which is the time for reading 512 bytes of memory cells. However, the invention obtains first the address of memory cells to be verified from a RAM and then verifies only the two memory cells at the corresponding address. Therefore, it needs 50 ns*512+500 ns*2=26.6 us, which is time for reading RAM (50 ns*512) plus time for reading two memory cells (500 ns*2).

The invention is not limited by performing the verification process in program flow, any other process, such as a soft-program flow or pre-program flow. For example, the pre-program process is performed in an erase flow for increasing stability of the erased flash memory data. The verification procedure is for reading, comparing and recording a verification result of the memory cells corresponding to the pre-program process to verify whether the data status is correct. Or the verification process is a soft-program process. The soft-program process is for diminishing distribution of threshold voltages of the memory cells. The verification procedure is also used to verify the memory cells corresponding to the soft-program process.

Moreover, in the step of reading the memory-cell verification data of the embodiment, if an address of a memory cell failed when verification is read, continuously read the remained memory-cell verification data in the flash memory RAM while performing a verification procedure on the memory cell corresponding to the address. For example, in the first programming (not limited to any form of programming, can be a program performing a read operation according to data, a soft-program or pre-program process), all the memory cells are still not verified, and thus after the first address of the memory cell in the memory-cell verification data is read, it starts to verify the memory cell corresponding to the first address. At the same time, the second, the third, to the last address of memory cell is continuously read and recorded for verifying the memory cells. As a result, it does not need to waste time in waiting for reading the verification RAM.

The verification process disclosed by the above embodiment of the invention will not read the memory cells first but obtain which memory cells need to be verified from the RAM and then perform a verification procedure only on the memory cells required to be verified. Therefore, the time for verification process can be greatly reduced.

While the invention has been described by way of example and in terms of a preferred embodiment, it is to be understood that the invention is not limited thereto. On the contrary, it is intended to cover various modifications and similar arrangements and process, and the scope of the appended claims therefore should be accorded to the broadest interpretation so as to encompass all such modifications and similar arrangements and processes.

What is claimed is:

1. A verification process for verifying a status of a data memory in a memory system after alteration, wherein the data memory comprises a plurality of memory cells and the memory system further comprises a temporary memory for storing a memory-cell verification data, the verification process comprising:
performing a first verification procedure on said data memory;
storing a failure of verification in said temporary memory; and
performing a second verification procedure on the memory cells following the failure of verification.

2. The verification process according to claim 1, further comprising:
recording an address of each of the memory cells failed during the first verification procedure into the temporary memory and updating the memory-cell verification data.

3. The verification process according to claim 2, wherein said step of performing the second verification procedure further comprises:
when the address of any memory cell failed in verification is read, read the memory-cell verification data from the temporary memory when performing the second verification procedure on the memory cell of the corresponding addresses.

4. The verification process according to claim 3, wherein the verification procedure is performed after a program process and the program process is for programming the memory cells according to data which are to be written into the memory cells.

5. The verification process according to claim 3, wherein the verification process is performed after a pre-program process and the pre-program process is performed in an erase flow.

6. The verification process according to claim 3, wherein the verification process is performed after a soft-program process and the soft-program process is for varying distribution of threshold voltages of the memory cells.

7. The verification process according to claim 1, wherein the temporary memory is a RAM (random access memory).

8. The verification process according to claim 1, wherein the temporary memory is a DRAM (dynamic RAM)
